(19) United States
(12) Patent Application Publication
(10) Pub. No.: US 2026/0162700 A1
(43) Pub. Date: Jun. 11, 2026

(54) SEMICONDUCTOR MEMORY DEVICE, NON-VOLATILE MEMORY DEVICE, AND DQS REPLICATING METHOD THEREOF

(71) Applicant: SAMSUNG ELECTRONICS CO., LTD., Suwon-si (KR)

(72) Inventors: Dongkyu JUNG, Suwon-si (KR); Jehoon KIM, Suwon-si (KR); Soohwan YOO, Suwon-si (KR)

(73) Assignee: SAMSUNG ELECTRONICS CO., LTD., Suwon-si (KR)

(21) Appl. No.: 19/330,215

(22) Filed: Sep. 16, 2025

(30) Foreign Application Priority Data
Dec. 9, 2024 (KR) 10-2024-0181138

(51) Int. Cl. G11C 7/10; G11C 7/22

(52) U.S. Cl. CPC G11C 7/1048; G11C 7/22

(57) ABSTRACT

A semiconductor memory device that receives a data DQ signal and a data strobe DQS signal from an external device includes a DQS clock tree including a first DQS input buffer that receives the DQS signal for sampling the DQ signal, and a DQS oscillator that simulates a path of the DQS clock tree using a second DQS input buffer and one or more repeaters. The DQS oscillator matches an input terminal voltage of the second DQS input buffer to an input terminal voltage of the first DQS input buffer using a termination circuit.

### CROSS-REFERENCE TO RELATED APPLICATION

This application claims priority under 35 U.S.C. § 119 to Korean Patent Application No. 10-2024-0181138 filed on Dec. 9, 2024 in the Korean Intellectual Property Office, the disclosure of which being incorporated by reference herein in its entirety.

### BACKGROUND

Embodiments described herein relate to a semiconductor device, and more specifically, to an oscillator simulating a data strobe signal, a semiconductor memory device including the same, a non-volatile memory device, and a method for simulating data strobe signal thereof.

In recent mobile systems and computer systems, storage devices are equipped with high-capacity flash memories that apply high-speed interfaces in response to the increasing demand for high-speed and high-capacity. In particular, in high-speed interfaces, an unmatched DQS structure is applied in which the delay of the DQ signal path and the delay of the DQS signal path are different for the purpose of signal integrity and power reduction.

In memory devices to which an unmatched DQS structure is applied, the skew of the DQ signal and the DQS signal is first adjusted through training. However, the voltage/temperature variation characteristics of the delay of the DQ signal path and the delay of the DQS signal path are different. Therefore, if voltage or temperature changes occur in the future, retraining is required to readjust the delay of the DQS signal.

### SUMMARY

It is an aspect to provide a DQS oscillator having the same voltage swing level as a voltage input from an actual DQS clock tree in a memory device applying an unmatched DQS structure.

According to an aspect of one or more embodiments, there is provided a semiconductor memory device that receives a data DQ signal and a data strobe DQS signal from an external device, the semiconductor memory device comprising a DQS clock tree including a first DQS input buffer configured to receive the DQS signal for sampling the DQ signal, and a DQS oscillator configured to simulate a path of the DQS clock tree using a second DQS input buffer and at least one repeater. The DQS oscillator matches an input terminal voltage of the second DQS input buffer to an input terminal voltage of the first DQS input buffer using a termination circuit.

According to another aspect of one or more embodiments, there is provided a method for simulating a DQS signal provided from an outside of a semiconductor memory device, the method comprising receiving a transmission voltage of the DQS signal from the outside, a transmission terminal resistance value for transmitting the DQS signal from the outside, and a first terminal resistance value of an input terminal of a first DQS input buffer for receiving the DQS signal of the semiconductor memory device, selecting a second terminal resistance value corresponding to the transmission voltage, the transmission terminal resistance value, and the first terminal resistance value, and setting an input terminal resistance of a second DQS input buffer of a DQS oscillator to the second terminal resistance value.

According to yet another aspect of one or more embodiments, there is provided a non-volatile memory device receiving a DQS signal from a memory controller, the non-volatile memory device comprising a first DQS input buffer configured to receive the DQS signal, and a DQS oscillator configured to count a path delay by simulating a path of the DQS signal. The DQS oscillator comprises an oscillator replica including a termination circuit, and a termination control logic configured to set a resistance value of the termination circuit.

### BRIEF DESCRIPTION OF THE FIGURES

The above and other aspects will become apparent by describing in detail embodiments thereof with reference to the accompanying drawings, in which:

FIG. 1 is a block diagram showing a memory system including a memory controller and a memory device according to an embodiment;

FIG. 2 is a diagram showing a DQS transmitter of the memory controller of FIG. 1 and an input terminal of a DQS clock tree of the memory device, according to an embodiment;

FIG. 3 is a block diagram briefly showing a propagation path of a DQ signal and a DQS signal of an unmatched type input method;

FIG. 4 is a block diagram showing a configuration of a DQS oscillator according to an embodiment;

FIG. 5 is a diagram showing a structure of an oscillator replica of the DQS oscillator of FIG. 4, according to an embodiment;

FIG. 6 is a diagram showing a connection relationship of a termination circuit, a DQS buffer, and a third repeater of the oscillator replica of FIG. 5, according to an embodiment;

FIG. 7 is a block diagram showing an exemplary configuration of a termination control logic of the DQS oscillator of FIG. 4, according to an embodiment;

FIG. 8 is a flowchart showing an exemplary operation of a DQS oscillator, according to an embodiment;

FIG. 9 is a table showing the DQS path of the DQS clock tree of an embodiment and the DQS replica path of the DQS oscillator, respectively, according to an embodiment;

FIG. 10 is a diagram showing a retraining procedure of a memory system according to an embodiment;

FIG. 11 is a block diagram showing a storage system including a non-volatile memory device, according to an embodiment; and

FIG. 12 is a cross-sectional view showing a memory system according to an embodiment.

### DETAILED DESCRIPTION

It is to be understood that both the foregoing general description and the following detailed description are exemplary, and it is to be considered that an additional description of various embodiments is provided. Reference signs are indicated in detail in the various embodiments, examples of which are indicated in the reference drawings. Wherever possible, the same reference numbers are used in the description and drawings to refer to the same or like parts.

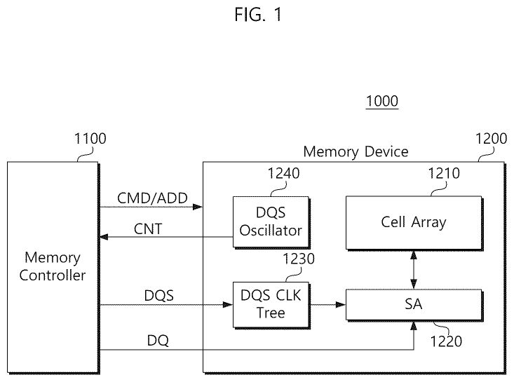

FIG. 1 is a block diagram showing a memory system including a memory device according to an embodiment. Referring to FIG. 1, a memory system 1000 may include a memory controller 1100 and a memory device 1200. For example, each of the memory controller 1100 and the memory device 1200 may be provided as one chip, one package, or one module. In an embodiment, the memory device 1200 may include a cell array 1210, a sense amplifier (SA) 1220, a DQS clock (CLK) tree 1230, and a DQS oscillator 1240. The memory device 1200 may be configured as a non-volatile memory device or a volatile memory device. That is, the memory system 1000 may be provided as a main memory such as a high bandwidth memory (HBM) or a storage device such as a solid state drive (SSD).

The memory controller 1100 may perform an access operation of writing data to the memory device 1200 or reading data stored in the memory device 1200. The memory controller 1100 may generate a command CMD and an address ADD for accessing the memory device 1200. In particular, the memory controller 1100 provides a data DQ signal and a data strobe DQS signal to transmit data, address, or the command. It is advantageous for data DQ signal and the data strobe DQS signal to be precisely matched to ensure data reliability.

The memory controller 1100 manages the input method of the DQ signal and the DQS signal provided to the memory device 1200 as an unmatched type. That is, the memory controller 1100 initially matches the skew of the DQ signal and the DQS signal through write training. However, a delay difference occurs later due to a difference in the characteristics of the DQ signal path and the DQS signal path depending on fluctuations in voltage or temperature. Therefore, retraining is performed to readjust the delay difference between the DQ signal path and the DQS signal path.

The memory controller 1100 requests the memory device 1200 to count the delay difference between the DQ signal path and the DQS signal path in order to check whether retraining is to be performed. Then, the memory device 1200 counts the delay difference tDQS2DQ using the DQS oscillator 1240 that simulates the DQS signal path. The counted delay difference value or count value CNT may be provided to the memory controller 1100.

The memory device 1200 outputs the read data requested by the memory controller 1100 to the memory controller 1100 or stores the data requested to be written by the memory controller 1100 in a memory cell of the cell array 1210.

The cell array 1210 includes memory cells arranged at intersections of word lines WLs and bit lines BLs. For example, if the memory device 1200 is a DRAM, DRAM cells (access transistors and cell capacitors) are located at intersections of word lines and bit lines of the cell array 1210, and the DRAM cells are connected to the sense amplifier (SA) 1220 through the bit lines.

If the memory device 1200 is a non-volatile memory device, the cell array 1210 may include a plurality of NAND cell strings. The cell array 1210 may include a plurality of memory cells forming a NAND cell string. The plurality of memory cells may be programmed, erased, and sensed by voltages provided to bit lines BLs or word lines WLs. The program operation may be performed in units of pages, and the erase operation may be performed in units of blocks. In this case, the sense amplifier 1220 may correspond to a page buffer. However, it will be well understood that the structure of the cell array 1210 is not limited to the above-described memory type and may be variously changed.

The sense amplifier (SA) 1220 writes a DQ signal input to a data line into the cell array 1210 or senses memory cells selected from the cell array 1210. The sense amplifier 1220 latches or samples the DQ signal input to the data line using a DQS signal provided via the DQS clock tree 1230. Therefore, if there is a problem in the matching of the DQ signal and the DQS signal, the signal integrity of the input data is damaged. The sense amplifier 1220 corresponds to a page buffer when the memory device 1200 is configured as a non-volatile memory device. The scope of the sense amplifier 1220 is not limited to a page buffer. That is, the sense amplifier 1220 may encompass all configurations that sample the DQ signal using the DQS signal in the memory device 1200 and store the sampled data in the cell array 1210.

The sense amplifier (SA) 1220 samples the DQ signal using the DQS signal. Therefore, the reliability of data stored in the memory device 1200 may be determined by DQS training for aligning the timing of the DQS signal and the DQ signal. In a non-aligned interface, the DQS signal path is longer than the DQ signal path. Therefore, in order to reduce the time for data training, it is advantageous to reduce the time to detect the DQS delay time.

The DQS clock (CLK) tree 1230 corresponds to a clock path for transmitting a DQS signal to the sense amplifier 1220. The DQS clock tree 1230 may be configured as an unmatched type in which the length of the DQS path is longer than the length of the DQ path. In this case, since the DQ delay time and the DQS delay time do not match each other, the DQS delay time needs to be detected separately. Since the length of the DQ path is generally short and the DQ delay time rarely occurs, detection of the DQS delay time is advantageous. If the temperature or voltage level changes, the DQS delay time also changes, so it is advantageous to detect the DQS delay time whenever the temperature or voltage level changes.

The DQS oscillator 1240 counts the delay time of the DQS path according to the request of the memory controller 1100, and the counted DQS delay time CNT is provided to the memory controller 1100 and used as determination information for retraining. The DQS oscillator 1240 includes an oscillator circuit that simulates the delay difference between the DQ path and the DQS path. The DQS oscillator 1240 may drive the oscillator circuit that simulates the DQS path and count the delay time of the DQS path. In practice, the DQS oscillator 1240 may be configured using a DQS buffer, or repeater used in the DQS clock tree 1230.

In an embodiment, the DQS oscillator 1240 may match the level of the input signal applied to the DQS buffer and the level of the input signal of the DQS buffer of the DQS clock tree 1230. That is, the DQS oscillator 1240 may simulate the DQS clock tree 1230 by using the same input voltage as the DQS buffer input signal of the DQS clock tree 1230 by using a termination circuit. To this end, the DQS oscillator 1240 may include a DQS buffer, at least one repeater, a termination circuit, and termination control logic. The detailed structure of the DQS oscillator 1240 will be described in more detail through the drawings described below.

In an embodiment, the memory device 1200 may include a non-volatile memory. The non-volatile memory may include non-volatile memory cells such as a flash memory, a resistive RAM (RRAM), a phase change RAM (PRAM), a magnetic RAM (MRAM), a ferroelectric random access memory (FRAM), and/or a spin transfer torque random access memory (STT-RAM). In some embodiments, the memory device 1200 may include volatile memory such as a Dynamic Random Access Memory (DRAM). In some embodiments, the memory device 1200 may be implemented to include storage devices such as buffers and/or registers. In some embodiments, the memory device 1200 may be implemented to include heterogeneous memory and/or storage devices.

As described above, the DQS oscillator 1240 may simulate the operation of the DQS clock tree 1230 by using an input signal having the same level as the signal level of the DQS signal received by the DQS clock tree 1230. Therefore, it is possible to block a count error of the DQS oscillator 1240 due to a difference in the level of the voltage swing width or skew caused by a difference in the input signal levels of the DQS buffers.

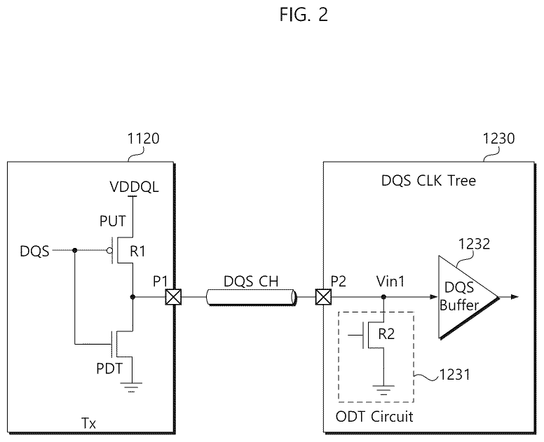

FIG. 2 is a diagram showing the input structure of the DQS transmitter of the memory controller illustrated in FIG. 1 and the DQS clock tree of the memory device, according to an embodiment. Referring to FIG. 2, the DQS transmitter 1120 transmits a DQS signal using a transmission voltage VDDQL that is lower than an internal voltage VDDQ of the memory controller 1100 to reduce channel current and/or to implement low power. Then, the DQS clock tree 1230 of the memory device 1200 receives the DQS signal transmitted using the transmission voltage VDDQL.

The DQS transmitter 1120 transmits the DQS signal to the memory device 1200 using the transmission voltage VDDQL that is lower than the internal voltage VDDQ of the memory controller 1100. Since the transmission voltage VDDQL is much lower than the internal voltage VDDQ, it may be possible to reduce the channel current for transmitting the DQS signal. Therefore, the power for signal transmission of the memory controller 1100 may be reduced when using the transmission voltage VDDQL. The DQS transmitter 1120 includes a pull-up transistor PUT and a pull-down transistor PDT for pulling up or pulling down the DQS channel DQS CH through a first pad P1 with the transmission voltage VDDQL.

The DQS clock tree 1230 receives the DQS signal through a second pad P2. An on-die-termination (hereinafter, ODT) circuit 1231 is connected to an input terminal of the DQS buffer 1232 of the DQS clock tree 1230. By adjusting an input terminal resistance of the DQS buffer 1232 using the ODT circuit 1231, a reflection of the DQS signal transmitted through the DQS channel DQS CH may be minimized. The resistance value of the ODT circuit 1231 connected to the input terminal of the DQS buffer 1232 may be referred to as ‘R2’, and the input voltage corresponding to the swing width of the DQS signal transmitted to the input terminal of the DQS buffer 1232 is referred to as the first input voltage ‘Vin1’.

When the pull-up transistor PUT of the DQS transmitter 1120 is turned on (=DQS high level), the resistance value between the pull-up transistor PUT and the first pad P1 or the pull-up transistor PUT and the second pad P2 is referred to as ‘R1’. Then, the first input voltage ‘Vin1’ may be expressed by the following Equation 1.

$$Vin 1 = V D D Q L \times \frac{R 2}{R 1 + R 2} \qquad ( Equation 1 )$$

The level of the input terminal voltage swing of the DQS buffer 1232 is determined according to the first input voltage ‘Vin1’ transmitted from the DQS transmitter 1120. The first input voltage ‘Vin1’ is transmitted at a level lower than the transmission voltage VDDQL, and propagation of the DQS signal occurs under these conditions in the DQS buffer 1232.

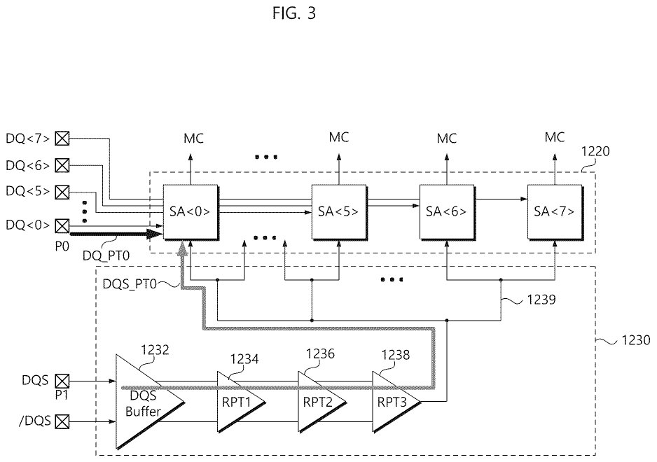

FIG. 3 is a block diagram briefly showing a propagation path of DQ signals and DQS signals in an unmatched type interface method, according to an embodiment. Referring to FIG. 3, DQ signals DQ<0> to DQ<7> are transmitted to the sense amplifier 1220 through pads, and DQS signals (DQS, /DQS) are input to a DQS buffer 1232 of the DQS clock tree 1230 through pads. In an embodiment, the DQS clock tree 1230 may include a DQS buffer 1232, a plurality of repeaters 1234, 1236 and 1238, and branch paths 1239.

The sense amplifier (SA) 1220 may receive DQ signals DQ<0> to DQ<7> from the memory controller 1100. The sense amplifier 1220 may receive a DQS signal through the DQS clock tree 1230. The sense amplifier 1220 may sample the DQ signals DQ<0> to DQ<7> using the DQS signal and store the sampled data in the memory cells MCs included in the memory device 1200. Here, the sense amplifier 1220 may be used to encompass circuits that sample the DQ signals DQ<0> to DQ<7> using the DQS signal. For example, the sense amplifier 1220 may correspond to a page buffer that writes or senses data in the case of a non-volatile memory device.

The DQS clock tree 1230 may include the DQS buffer 1232, the plurality of repeaters 1234, 1236 and 1238, and the branch paths 1239. In an unmatched type interface where the length of the DQS path is longer than the length of the DQ path, a delay difference due to the length of the path occurs. In particular, when the temperature or voltage level changes, the DQS delay time also changes. Therefore, it is advantageous to detect the DQS delay time whenever the temperature or voltage level changes. That is, since the DQ delay time and the DQS delay time do not match each other, it is advantageous to detect the DQS delay time separately. The DQS delay time will be performed in a DQS oscillator 1240 described later.

The path DQ_PT0 of the DQ signal DQ<0> received from the sense amplifier SA<0> and the path DQS_PT0 of the DQS signal are illustrated as an example. Considering the path DQ_PT0 of the DQ signal DQ<0>, the sense amplifier SA<0> may be placed relatively adjacent to the pad P0. Accordingly, not only is the length of the path DQ_PT0 of the DQ signal DQ<0> short, but the number of branches used to implement the path DQ_PT0 of the DQ signal DQ<0> may also be small. On the other hand, the path DQS_PT0 of the DQS signal from the pad P1 to the sense amplifier SA<0> is relatively long compared to the path DQ_PT0 of the DQ signal DQ<0>.

As described above, in the memory device 1200 to which the DQ signal and the DQS signal of the unmatched type interface are applied, a difference in the path of the DQ signal and the path of the DQS signal occurs. Therefore, the matching error of the DQ signal and the DQS signal may be minimized depending on the replication accuracy of the DQS oscillator 1240 that counts the DQS delay time of the DQS clock tree 1230.

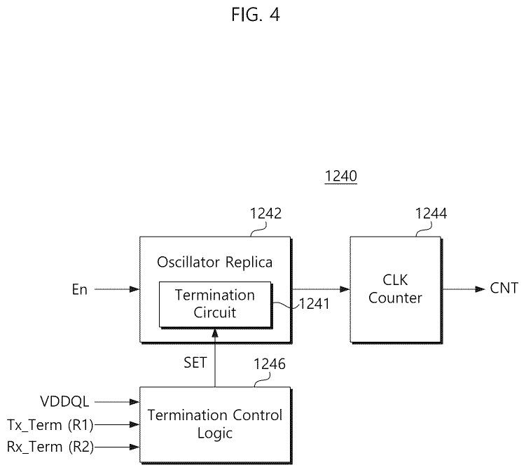

FIG. 4 is a block diagram showing the configuration of a DQS oscillator according to an embodiment. Referring to FIG. 4, the DQS oscillator 1240 includes an oscillator replica 1242 including a termination circuit 1241, a clock (CLK) counter 1244, and a termination control logic 1246.

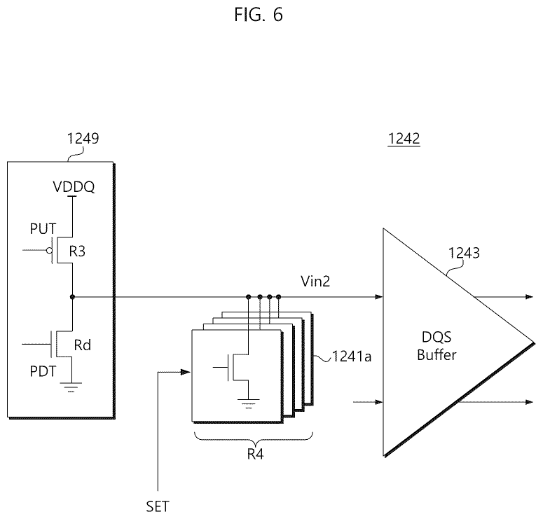

The oscillator replica 1242 includes a replica circuit (not shown) that replicates a DQS path of the DQS clock tree (1230, see FIG. 2) and a termination circuit 1241. The replica circuit of the oscillator replica 1242 may include paths having the same structure as the DQS buffer 1232 and repeaters 1234, 1236 and 1238 of the DQS clock tree 1230. In particular, the oscillator replica 1242 may set a terminal resistance value of the input terminal of a DQS buffer 1243 of the replica circuit (see FIG. 6) using the termination circuit 1241. To this end, the termination circuit 1241 may receive a setting signal SET from the termination control logic 1246. The oscillator replica 1242 may be activated in response to an enable signal En after the setting of the termination circuit 1241 is completed.

The clock (CLK) counter 1244 counts the DQS replica signal generated from the oscillator replica 1242. Then, the clock counter 1244 outputs the count result as a count value CNT. The count value CNT may be transmitted to the memory controller 1100 and used as information for determining whether to execute retraining.

The termination control logic 1246 sets the termination circuit 1241 of the oscillator replica 1242. The termination control logic 1246 may be provided with the transmission voltage VDDQL of the memory controller 1100, a transmission termination resistance (Tx_Term, R1), and a reception termination resistance (Rx_Term, R2) of the memory device 1200 to set a resistance value of the termination circuit 1241. The termination control logic 1246 determines the setting value of the resistance value of the termination circuit 1241 based on the received information (e.g., VDDQL, R1, R2). When setting of the termination circuit 1241 is completed, the oscillator replica 1242 will be activated by the enable signal En.

The configuration of the DQS oscillator 1240 has been exemplarily described above. However, the configuration of the DQS oscillator 1240 may be changed in various ways except for the termination circuit 1241 or the termination control logic 1246.

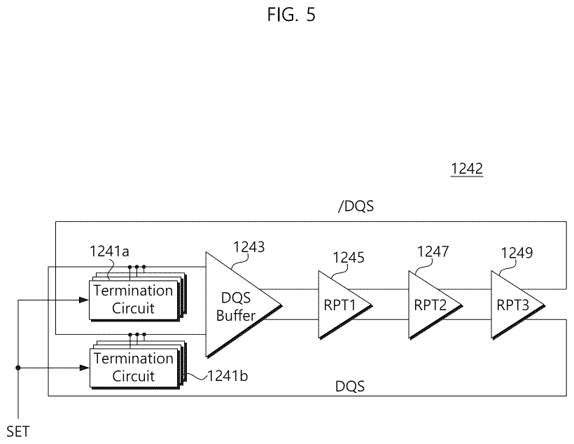

FIG. 5 is a drawing showing the structure of the oscillator replica of FIG. 4, according to an embodiment. Referring to FIG. 5, the oscillator replica 1242 uses the same configuration as the DQS clock tree (1230, see FIG. 3), but is configured in the form of a ring counter that uses the output DQS signal as an input again. In particular, the oscillator replica 1242 may further include a configuration for adjusting the terminal resistance of the input terminal of the DQS buffer 1243. In an embodiment, the oscillator replica 1242 may include termination circuits 1241a and 1241b, the DQS buffer 1243, a first repeater 1245, a second repeater 1247, and a third repeater 1249.

Each of the termination circuits 1241a and 1241b provides a termination resistance value ‘R4’ to each of the input terminals of the DQS buffer 1243. For example, each of the termination circuits 1241a and 1241b may include a plurality of transistors connected in parallel between the input terminal and ground to adjust the termination resistance value ‘R4’ of the input terminal. According to a setting signal SET from the termination control logic 1246, selected transistors among the plurality of transistors may be turned on. The input terminal resistance ‘R4’ of the DQS buffer 1243 may be set according to the number of transistors turned on. However, the resistance setting method of the termination circuits 1241a and 1241b may be implemented in various ways. For example, a method using a fuse, an e-fuse, etc., or a method using a variable resistance element may be included.

The DQS buffer 1243 receives feedback of DQS replica signals (DQS, /DQS) output from the third repeater 1249. The DQS buffer 1243 may be formed in a structure that receives DQS replica signals (DQS, /DQS) provided in a differential type. However, embodiments are not limited thereto, and embodiments are effective not only for a differential type but also for a single-ended type DQS signal.

The first to third repeaters 1245, 1247 and 1249 sequentially delay the DQS replica signals (DQS, /DQS) output from the DQS buffer 1243. Then, the delayed DQS replica signals (DQS, /DQS) are fed back to the DQS buffer 1243. The first to third repeaters 1245, 1247 and 1249 may be configured in the form of an analog buffer having a CMOS structure, for example. In particular, the resistance value (hereinafter, R3) of the pull-up transistor of the third repeater 1249 may be used as resistance setting information of the termination circuits 1241a and 1241b. Here, an embodiment is described by using the oscillator replica 1242 using the first to third repeaters 1245, 1247 and 1249, but the number of repeaters is not limited to the above-described example. The number of repeaters may be changed variously depending on the DQS clock tree 1230 being simulated.

The structure of the oscillator replica 1242 described above is designed to have substantially the same configuration and characteristics as the DQS clock tree 1230 of FIG. 3, except for the termination circuits 1241a and 1241b. However, the input voltage ‘Vin1’ of the DQS buffer 1232 of the DQS clock tree 1230 depends on a relatively low transmission voltage VDDQL. Therefore, it is advantageous to set the termination circuits 1241a and 1241b so that the input voltage ‘Vin2’ of the DQS buffer 1243 has the same swing width as the input voltage ‘Vin1’ of the DQS buffer 1232.

FIG. 6 is a diagram showing a connection relationship of the termination circuit of the oscillator replica, the DQS buffer, and the third repeater of FIG. 5. Referring to FIG. 6, the DQS signal output from the third repeater 1249 may be transmitted as the input voltage of the DQS buffer 1243. At this time, the resistance value of the pull-up transistor PUT of the third repeater 1249 (hereinafter, the pull-up resistance value) is referred to as ‘R3’. The terminal resistance value set by the first termination circuit 1241a is referred to as ‘R4’, and the voltage input to the DQS buffer 1243 is referred to as the second input voltage ‘Vin2’.

The third repeater 1249 feeds back the delayed DQS replica signal and transmits the delayed DQS replica signal back to the DQS buffer 1243. The third repeater 1249 may be, for example, an analog buffer structure generally composed of a pull-up transistor PUT and a pull-down transistor PDT. At this time, the level of the DQS replica signal is transmitted to the input terminal of the DQS buffer 1243 through the pull-up transistor PUT driven by the internal voltage VDDQ.

The first termination circuit 1241a sets the input terminal resistance ‘R4’ of the input terminal of the DQS buffer 1243 in response to the setting signal SET from the termination control logic 1246. The first termination circuit 1241a may include a plurality of transistors connected in parallel between the input terminal and the ground in order to set the size of the input terminal resistance ‘R4’ of the input terminal. The transistors selected from among the plurality of transistors may be turned on according to the setting signal SET from the termination control logic 1246. The input terminal resistance ‘R4’ of the DQS buffer 1243 may be set according to the number of multiple turn-on transistors.

Depending on the setting of the input terminal resistance ‘R4’ of the DQS buffer 1243, the level of the second input voltage ‘Vin2’ distributed to the input terminal of the DQS buffer 1243 may be expressed by the following Equation 2.

$$Vin 2 = V D D Q \times \frac{R 4}{R 3 + R 4} \qquad ( Equation 2 )$$

Here, the pull-up resistance ‘R3’ of the third repeater 1249 is provided as a fixed value by the circuit element constituting the oscillator replica 1242. The internal voltage VDDQ of the memory device 1200 may also be provided as a fixed value specified in a specification. Therefore, the second input voltage ‘Vin2’ varies according to the size of the input terminal resistance ‘R4’. The termination control logic (1246, see FIG. 4) may set the size of the second input voltage ‘Vin2’ by adjusting the input terminal resistance ‘R4’. Equation 3 may be used to select the optimal input terminal resistance ‘R4’.

$$Vin 2 = Vin 1 \qquad ( Equation 3 )$$

$$V D D Q \times \frac{R 4}{R 3 + R 4} = V D D Q L \times \frac{R 2}{R 1 + R 2}$$

When the input voltage of the DQS buffer 1243 of the DQS oscillator 1240, i.e., the second input voltage ‘Vin2’, and the input voltage of the DQS buffer 1232 of the DQS clock tree 1230, i.e., the first input voltage ‘Vin1’, become the same level, the matching error may be minimized. The first input voltage ‘Vin1’ is determined by the transmission voltage VDDQL, the transmission terminal resistance (Tx_Term, R1), and the reception terminal resistance (Rx_Term, R2) of the memory controller 1100. The pull-up resistance ‘R3’ of the third repeater 1249 may be a value already obtained as a fixed value. Therefore, the termination control logic 1246 may determine the input terminal resistance ‘R4’ of the DQS buffer 1243 using the transmission voltage VDDQL, the transmission terminal resistance (Tx_Term, R1), and the reception terminal resistance (Rx_Term, R2).

The method of determining the input terminal resistance ‘R4’ of the DQS buffer 1243 through the structure of the oscillator replica 1242 has been described above. The input terminal resistance ‘R4’ that may minimize the matching error may be calculated using the transmission voltage VDDQL, the transmission terminal resistance (Tx_Term, R1), and the reception terminal resistance (Rx_Term, R2).

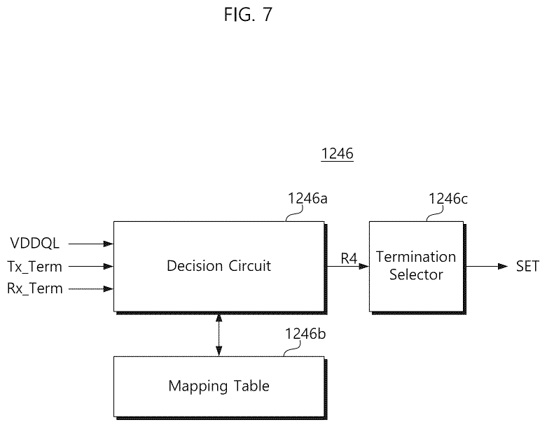

FIG. 7 is a block diagram showing an exemplary configuration of the termination control logic of FIG. 4, according to an embodiment. Referring to FIG. 7, the termination control logic 1246 may include a decision circuit 1246a, a mapping table 1246b, and a termination selector 1246c.

The decision circuit 1246a determines an input terminal resistance ‘R4’ using the transmission voltage VDDQL, the transmission terminal resistance (Tx_Term, R1), and the reception terminal resistance (Rx_Term, R2). Upon receiving the transmission voltage VDDQL, the transmission terminal resistance (Tx_Term, R1), and the reception terminal resistance (Rx_Term, R2), the decision circuit 1246a may use the information to calculate an input terminal resistance ‘R4’ of the DQS buffer 1243 that satisfies Equation 3. In an embodiment, the decision circuit 1246a may select the input terminal resistance ‘R4’ satisfying Equation 3 through the mapping table 1246b. The method of determining the input terminal resistance ‘R4’ using the transmission voltage VDDQL, the transmission terminal resistance (Tx_Term, R1), and the reception terminal resistance (Rx_Term, R2) is not limited to the examples described above, and various methods may be used.

The mapping table 1246b stores the input terminal resistance ‘R4’ mapped to various values of the transmission voltage VDDQL, the transmission terminal resistance (Tx_Term, R1), and the reception terminal resistance (Rx_Term, R2). That is, the input terminal resistance ‘R4’ corresponding to various pre-calculated transmission/reception environments and/or termination resistance values is stored in the mapping table 1246b. Therefore, when using the mapping table 1246b, it will be possible to derive the input terminal resistance ‘R4’ at high speed.

The termination selector 1246c receives the input terminal resistance ‘R4’ determined by the decision circuit 1246a. Then, the termination selector 1246c generates a setting signal SET for setting the termination circuits 1241a and 1241b with the received input terminal resistance ‘R4’. For example, the termination selector 1246c may set the input terminal resistance ‘R4’ by determining the number of transistors that are turned on among the plurality of transistors constituting the termination circuits 1241a and 1241b. The setting signal SET will be transmitted to the gates of the plurality of transistors constituting the termination circuits 1241a and 1241b to turn on only the selected transistors.

As described above, the termination control logic 1246 may set the resistance value ‘R4’ of the termination circuits 1241a and 1241b based on the transmission voltage VDDQL, the transmission termination resistance (Tx_Term, R1), and the reception termination resistance (Rx_Term, R2). The configuration of the illustrated termination control logic 1246 is only an example, and it will be understood that various changes are possible.

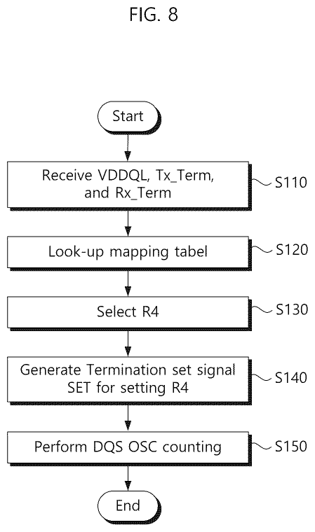

FIG. 8 is a flowchart showing the operation of the DQS oscillator, according to an embodiment. Referring to FIG. 8, when a retraining request occurs from the memory controller 1100, the DQS oscillator 1240 determines the input terminal resistance ‘R4’. Then, the DQS oscillator 1240 sets the termination circuits 1241a and 1241b to the determined input terminal resistance ‘R4’ and then starts a count operation for measuring the DQS delay.

In step S110, the DQS oscillator 1240 receives the transmission voltage VDDQL, the transmission terminal resistance (Tx_Term, R1) of the memory controller 1100, and the reception terminal resistance (Rx_Term, R2) of the memory device 1200. That is, the termination control logic (1246, see FIG. 4) receives information (VDDQL, R1, R2) for determining the input terminal resistance ‘R4’ of the DQS buffer (1243, see FIG. 5).

In step S120, the decision circuit 1246a of the termination control logic 1246 searches the mapping table 1246b. The decision circuit 1246a searches for the input terminal resistance ‘R4’ mapped to the received information (VDDQL, R1, R2).

In step S130, the decision circuit 1246a selects the input terminal resistance ‘R4’ from the mapping table 1246b. The selected input terminal resistance ‘R4’ is provided to the termination selector 1246c by the decision circuit 1246a.

In step S140, the termination selector 1246c generates a setting signal SET corresponding to the selected input terminal resistance ‘R4’. The input terminal resistance ‘R4’ of the termination circuits 1241a and 1241b may be set by the generated setting signal SET.

In step S150, the DQS oscillator 1240 activates the oscillator replica 1242 under the condition of the termination circuits 1241a and 1241b set to the input terminal resistance ‘R4’ and counts the DQS delay through the DQS replica signal. Then, the clock counter (1244, see FIG. 4) outputs the count result as a count value CNT. The count value CNT may be transmitted to the memory controller 1100 and used as information for determining whether to execute retraining.

In the above, the setting procedure of the input terminal resistance ‘R4’ of the DQS buffer 1243 performed in the DQS oscillator 1240 has been exemplarily described. The setting of the input terminal resistance ‘R4’ of the DQS buffer 1243 may be performed according to the retraining request of the memory controller 1100. After performing the setting procedure of the input terminal resistance ‘R4’ of the DQS buffer 1243, the DQS oscillator 1240 counts the DQS delay and provides the result to the memory controller 1100. The memory controller 1100 may perform retraining according to the count value CNT of the DQS delay.

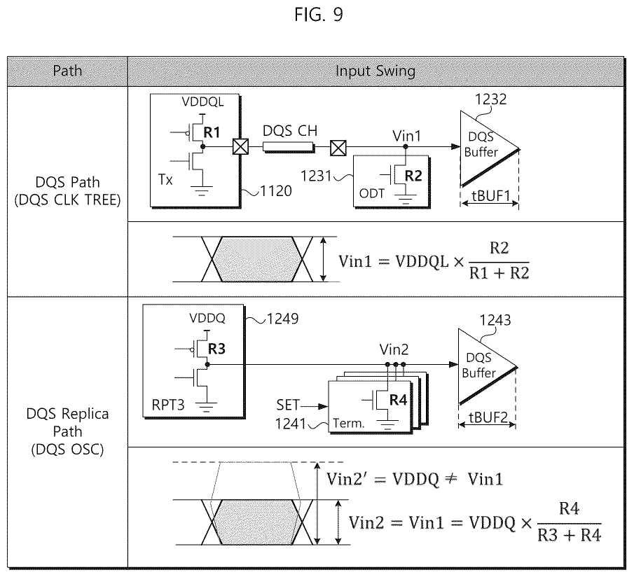

FIG. 9 is a table showing the DQS path of the DQS clock tree and the DQS replica path of the DQS oscillator, respectively, according to an embodiment. Referring to FIG. 9, the characteristics of the DQS path input to the DQS buffer 1232 of the DQS clock tree (1230, see FIG. 3) and the DQS replica path input to the DQS buffer 1243 of the DQS oscillator 1240 are illustrated.

According to the DQS path, the DQS transmitter 1120 transmits the DQS signal to the memory device 1200 using a transmission voltage VDDQL that is lower than the internal voltage VDDQ of the memory controller 1100. When the pull-up transistor PUT of the DQS transmitter 1120 is turned on (DQS high level), the resistance value between the pull-up transistor PUT and the first pad P1 or the pull-up transistor PUT and the second pad P2 becomes ‘R1’. A DQS signal is input to a DQS clock tree 1230 via a DQS channel. An ODT circuit 1231 having a resistance value of ‘R2’ is connected to an input terminal of a DQS buffer 1232 of the DQS clock tree 1230. Then, a first input voltage ‘Vin1’ of Equation 1 corresponding to the swing width of the DQS signal will be transmitted to the input terminal of the DQS buffer 1232.

The input terminal voltage swing width of the DQS buffer 1232 is determined according to the first input voltage ‘Vin1’ transmitted to the input terminal of the DQS buffer 1232 of the DQS clock tree 1230. The first input voltage ‘Vin1’ is transmitted at a level lower than the transmission voltage VDDQL, and propagation of the DQS signal occurs in the DQS buffer 1232 under these conditions. At this time, the first delay offset ‘tBUF1’ of the DQS buffer 1232 occurs under the condition of the first input voltage ‘Vin1’. The first delay offset ‘tBUF1’ occurs relatively large at low voltage.

According to the DQS replica path, the third repeater 1249 feeds back the DQS replica signal and transmits the DQS replica signal back to the DQS buffer 1243. At this time, the DQS buffer 1243 is driven by the internal voltage VDDQ, and the DQS replica signal is transmitted to the input terminal of the DQS buffer 1243 through the pull-up transistor PUT of the resistance value ‘R3’. The termination circuit 1241 is set to the resistance value ‘R4’ by the setting signal SET. According to the setting of the input terminal resistance ‘R4’ of the DQS buffer 1243, a DQS replica signal having a swing width corresponding to the second input voltage ‘Vin2’ of Equation 3 is transmitted to the input terminal of the DQS buffer 1243.

In the DQS replica path implemented by the DQS oscillator 1240 according to an embodiment, the voltage swing width of the DQS replica signal is determined according to the second input voltage ‘Vin2’ transmitted to the input terminal of the DQS buffer 1243. The second input voltage ‘Vin2’ is a voltage adjusted so that the internal voltage VDDQ matches the first input voltage ‘Vin1’ through the termination circuit 1241. In the case where the voltage swing width of the DQS replica signal is determined by the internal voltage VDDQ without using the termination circuit 1241, a DQS replica signal having a voltage swing width of a relatively high level (Vin2′) will be input to the DQS buffer 1243.

In the DQS buffer 1243, propagation of the DQS replica signal occurs under these conditions. A second delay offset ‘tBUF2’ of the DQS buffer 1243 occurs under the condition of the second input voltage ‘Vin2’. According to an embodiment, the second delay offset ‘tBUF2’ may occur substantially the same as the first delay offset ‘tBUF1’ of the DQS buffer 1232. This is because the second input voltage ‘Vin2’ is set to the same level as the first input voltage ‘Vin1’ by the termination circuit 1241.

In the above, the matching effect of the DQS oscillator 1240 and the DQS clock tree 1230 using the termination circuit 1241 according to an embodiment has been described. Through application of the termination circuit 1241 according to an embodiment, the input voltages (Vin1, Vin2) of the DQS buffers 1232 and 1243 of the DQS clock tree 1230 and the DQS oscillator 1240 may be provided at the same level. Accordingly, the delay offsets ‘tBUF1’ and ‘tBUF2’ of the DQS buffers 1232 and 1243 of the DQS clock tree 1230 and the DQS oscillator 1240 may be matched, and this effect may be equally applied to repeaters. Accordingly, the matching error of the DQS oscillator 1240 caused by the difference in the input voltage level may be eliminated or minimized.

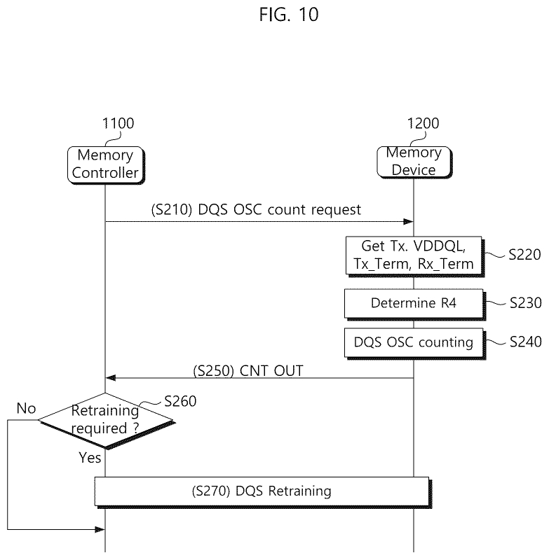

FIG. 10 is a diagram showing a retraining procedure of a memory system according to an embodiment. Referring to FIG. 10, a memory controller 1100 requests a count value CNT of a DQS oscillator 1240 to determine whether DQS retraining of a memory device 1200 is to be performed. Then, the memory device 1200 sets a termination circuit 1241 of the DQS oscillator 1240 and then counts the delay of a DQS replica signal. The delay count value CNT of the DQS replica signal is transmitted to the memory controller 1100, and this is used as information for determining whether DQS retraining is to be performed.

In step S210, the memory controller 1100 requests a delay count value CNT of a DQS replica signal of the DQS oscillator 1240. The request for the delay count value CNT is based on the determination of the memory controller 1100 according to the change in temperature or voltage.

In step S220, the memory device 1200 receives the transmission voltage VDDQL, the transmission terminal resistance (Tx_Term, R1) of the memory controller 1100, and the reception terminal resistance (Rx_Term, R2) of the memory device 1200. That is, the termination control logic 1246 of the DQS oscillator 1240 receives information (VDDQL, R1, R2) for determining the input terminal resistance ‘R4’ of the DQS buffer 1243.

In step S230, the termination control logic 1246 determines the input terminal resistance ‘R4’ mapped to the transmission voltage VDDQL, the transmission terminal resistance (Tx_Term, R1), and the reception terminal resistance (Rx_Term, R2) of the memory device 1200. Then, the termination control logic 1246 sets the termination circuit 1241 to the determined input terminal resistance ‘R4’.

In step S240, the DQS oscillator 1240 activates the oscillator replica 1242 in a state where the termination circuit 1241 is set to the input terminal resistance ‘R4’ and counts the DQS delay.

In step S250, the memory device 1200 transmits the count value CNT of the DQS delay to the memory controller 1100.

In step S260, the memory controller 1100 determines whether retraining is to be performed based on the count value CNT received from the memory device 1200. If retraining is determined to be performed (S260, Yes), the procedure moves to step S270. On the other hand, if retraining is determined not to be performed (S260, No), the entire procedure is terminated.

In step S270, the memory controller 1100 performs retraining for matching the DQ signal and the DQS signal for the memory device 1200.

The above has briefly described the request and response occurring between the memory controller 1100 and the memory device 1200. The memory device 1200 according to an embodiment uses a DQS oscillator 1240 including a termination circuit 1241 capable of counting the DQS delay under conditions identical to or close to the driving conditions of the DQS clock tree 1230. Therefore, the matching error of the DQS oscillator 1240 and the DQS clock tree 1230 may be improved to count the DQS delay with high accuracy at high speed.

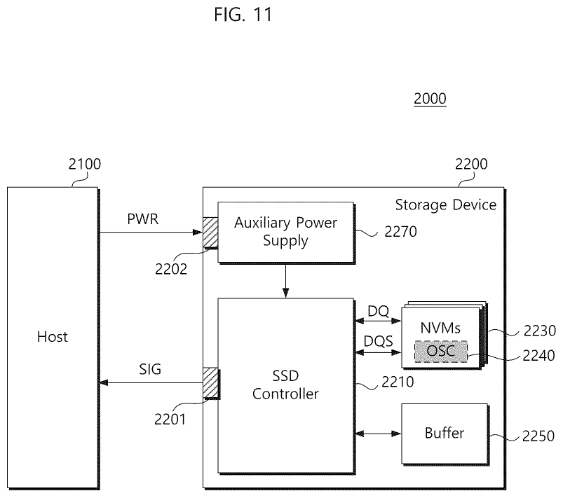

FIG. 11 is a block diagram showing a storage system including a non-volatile memory device, according to an embodiment. Referring to FIG. 11, the storage system 2000 includes a host 2100 and a storage device 2200 implemented as a solid state drive SSD. In an exemplary embodiment, the storage device 2200 may include a signal connector 2201, a power connector 2202, an SSD controller 2210, a plurality of non-volatile memories 2230 including the DQS oscillator 2240 according to the embodiments described with reference to FIGS. 1 to 10, a buffer 2250, and an auxiliary power supply 2270.

The storage device 2200 exchanges a signal SIG with the host 2100 through the signal connector 2201 and receives power PWR through the power connector 2202.

The SSD controller 2210 may control the plurality of non-volatile memories 2230 in response to a signal SIG received from the host 2100. The plurality of non-volatile memories 2230 may operate under the control of the SSD controller 2210. The auxiliary power supply 2270 is connected to the host 2100 through a power connector 2202. The auxiliary power supply 2270 may receive power PWR from the host 2100 and charge the storage device 2200. The auxiliary power supply 2270 may provide power to the storage device 2200 when the power supply from the host 2100 is not smooth. The buffer memory 2250 may be used as a buffer memory of the storage device 2200. In an exemplary embodiment, the SSD controller 2210 and each of the plurality of non-volatile memories 2230 may exchange a DQ signal and a DQS signal of an unmatched type input method.

Each of the plurality of non-volatile memories 2230 includes the DQS oscillator 2240 including an adjustable termination circuit as described above with respect to FIGS. 1-10. The DQS oscillator 2240 may count the DQS delay according to the request of the SSD controller 2210 and provide the DQS delay to the SSD controller 2210. Therefore, the simulation accuracy of the DQS oscillator 1240 that counts the DQS delay time of the DQS clock tree may be improved, and the matching error of the DQ signal and the DQS signal may be minimized.

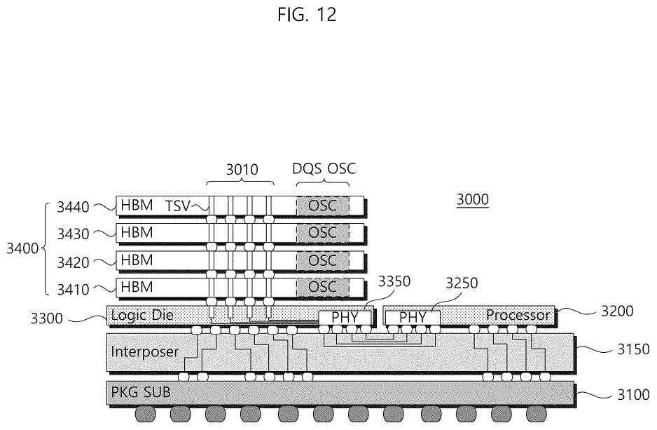

FIG. 12 is a cross-sectional view showing a memory system according to an embodiment. Referring to FIG. 12, a memory system 3000 implemented as a stacked semiconductor device may include a PCB substrate 3100, an interposer 3150, a processor 3200, a logic die 3300, and a high bandwidth memory 3400 comprising a plurality of DRAM dies 3410, 3420, 3430 and 3440.

The memory system 3000 connects the high bandwidth memory 3400 and the processor 3200 using the interposer 3150. The interposer 3150 is placed on the upper portion of the PCB substrate 3100 and is electrically connected to the PCB substrate 3100 through flip chip bumps FBs. The interposer 3150 may connect the logic die 3300 and the processor 3200. The interposer 3150 may connect the physical layer 3350 of the logic die 3300 and the physical layer 3250 of the processor 3200, and may provide physical paths formed using conductive materials. Accordingly, the logic die 3300 and the processor 3200 may transmit and receive signals to each other through the interposer 3150.

In an exemplary embodiment, each of the DRAM dies 3410, 3420, 3430 and 3440 may include a DQS oscillator DQS OSC including an adjustable termination circuit as described above with respect to FIGS. 1-10. The DQS oscillator DQS OSC may count the DQS delay and provide the DQS delay to the processor 3200 according to the request of the processor 3200. Therefore, the simulation accuracy of the DQS oscillator DQS OSC that counts the DQS delay time of the DQS clock tree may be improved, and the matching error between the DQ signal and the DQS signal may be minimized.

The above are specific embodiments for carrying out the embodiments of the present disclosure. In addition to the above-described embodiments, simple design changes or easily changeable embodiments may be made. In addition, various techniques can be easily modified and implemented using the embodiments. Therefore, the scope of the present disclosure should not be limited to the above-described embodiments, and should be defined by the claims and equivalents of the claims as well as the claims to be described later.

What is claimed is:

1. A semiconductor memory device that receives a data (DQ) signal and a data strobe (DQS) signal from an external device, the semiconductor memory device comprising:
a DQS clock tree including a first DQS input buffer configured to receive the DQS signal for sampling the DQ signal; and
a DQS oscillator configured to simulate a path of the DQS clock tree using a second DQS input buffer and at least one repeater,
wherein the DQS oscillator matches an input terminal voltage of the second DQS input buffer to an input terminal voltage of the first DQS input buffer using a termination circuit.

2. The semiconductor memory device of claim 1, wherein the DQS oscillator comprises:
an oscillator replica including the second DQS input buffer, the at least one repeater, and the termination circuit, the oscillator replica configured to propagate a DQS replica signal to simulate the path of the DQS clock tree;
a clock counter configured to count a delay of the DQS replica signal; and
a termination control logic configured to set a terminal resistance value of the termination circuit.

3. The semiconductor memory device of claim 2, wherein the termination control logic is configured to determine:
a second terminal resistance of an input terminal of the second DQS input buffer using a transmission voltage for transmitting the DQS signal from the external device,
a pull-up transmission terminal resistance for transmitting the DQS signal from the external device, and
a first terminal resistance of an input terminal of the first DQS input buffer.

4. The semiconductor memory device of claim 3, wherein the termination control logic includes a mapping table that maps the transmission voltage, the pull-up transmission terminal resistance, and the first terminal resistance to the second terminal resistance.

5. The semiconductor memory device of claim 3, wherein the termination control logic calculates the second terminal resistance using the transmission voltage, the pull-up transmission terminal resistance, an input terminal termination resistance, a pull-up resistance of the at least one repeater, and magnitude information of an internal voltage driving the DQS oscillator.

6. The semiconductor memory device of claim 2, wherein the termination circuit includes a plurality of transistors that set a second terminal resistance of an input terminal of the second DQS input buffer according to a setting signal of the termination control logic.

7. The semiconductor memory device of claim 2, wherein the terminal resistance value is set to a value for setting the input terminal voltage of the first DQS input buffer and the input terminal voltage of the second DQS input buffer to the same level.

8. A method for simulating a DQS signal provided from an outside of a semiconductor memory device, the method comprising:
receiving a transmission voltage of the DQS signal from the outside, a transmission terminal resistance value for transmitting the DQS signal from the outside, and a first terminal resistance value of an input terminal of a first DQS input buffer for receiving the DQS signal of the semiconductor memory device;
selecting a second terminal resistance value corresponding to the transmission voltage, the transmission terminal resistance value, and the first terminal resistance value; and
setting an input terminal resistance of a second DQS input buffer of a DQS oscillator to the second terminal resistance value.

9. The method of claim 8, wherein the selecting includes:
selecting the second terminal resistance value from a mapping table that maps the second terminal resistance value to the transmission voltage, the transmission terminal resistance value, and the first terminal resistance value.

10. The method of claim 8, wherein the selecting includes:
calculating the second terminal resistance value using a magnitude of a pull-up resistance value of a repeater that provides a DQS replica signal to the second DQS input buffer and an internal voltage that drives the DQS oscillator.

11. The method of claim 10, wherein the transmission voltage is lower than the internal voltage.

12. The method of claim 8, wherein the second terminal resistance value is set to match an input terminal voltage of the first DQS input buffer that receives the DQS signal in the semiconductor memory device and an input terminal voltage of the second DQS input buffer of the DQS oscillator.

13. The method of claim 12, wherein the second terminal resistance value is set to a same size as a swing width of the input terminal voltage of the first DQS input buffer and a swing width of the input terminal voltage of the second DQS input buffer.

14. The method of claim 8, further comprising:
after the input terminal resistance of the second DQS input buffer is set, counting a delay size of the DQS oscillator; and
transmitting the delay size to the outside.

15. The method of claim 14, further comprising:
retraining a DQS path through which the DQS signal is transmitted according to the delay size.

16. A non-volatile memory device that receives a DQS signal from a memory controller, the non-volatile memory device comprising:
a first DQS input buffer configured to receive the DQS signal; and
a DQS oscillator configured to count a path delay by simulating a path of the DQS signal,
wherein the DQS oscillator comprises:
an oscillator replica including a termination circuit; and
a termination control logic configured to set a resistance value of the termination circuit.

17. The non-volatile memory device of claim 16, wherein the oscillator replica comprises:
a second DQS input buffer whose input voltage is set by the termination circuit; and
at least one repeater configured to propagate a DQS replica signal that is output from the second DQS input buffer.

18. The non-volatile memory device of claim 17, wherein the termination control logic determines:
the resistance value of the termination circuit using a transmission voltage for transmitting the DQS signal from the memory controller,
a pull-up transmission terminal resistance value for transmitting the DQS signal from the memory controller, and
a terminal resistance value of an input terminal of the first DQS input buffer.

19. The non-volatile memory device of claim 18, wherein the termination control logic includes a mapping table that maps the resistance value of the termination circuit to the transmission voltage, the pull-up transmission terminal resistance value, and the terminal resistance value.

20. The non-volatile memory device of claim 17, wherein the termination control logic matches an input terminal voltage of the second DQS input buffer to an input terminal voltage of the first DQS input buffer using the termination circuit.
